(19) United States
(12) Patent Application Publication
(10) Pub. No.: US 2026/0019076 A1
(43) Pub. Date: Jan. 15, 2026

(54) DRIVING DEVICE FOR SWITCHING ELEMENT

(71) Applicant: KABUSHIKI KAISHA TOYOTA JIDOSHOKKI, Aichi (JP)

(72) Inventor: Yasushi NAKAMURA, Aichi (JP)

(73) Assignee: KABUSHIKI KAISHA TOYOTA JIDOSHOKKI, Aichi (JP)

(21) Appl. No.: 19/249,023

(22) Filed: Jun. 25, 2025

(30) Foreign Application Priority Data
Jul. 9, 2024 (JP) 2024-110342

(51) Int. Cl. H03K 17/284; H03K 17/082

(52) U.S. Cl. CPC H03K 17/284; H03K 17/0822

(57) ABSTRACT

A driving device for a switching element including a first terminal, a second terminal, and a control terminal includes a driver configured to switch the switching element on and off by generating a driving signal based on a control signal and by inputting the driving signal to the control terminal, a first resistor, and a second resistor. The driving device performs active control in which a voltage applied to the control terminal is adjusted during a transition period of switching of the switching element. A state of the driver includes a high output state, a low output state, and a high impedance state in which the driving signal is not input to the control terminal. The driving device performs the active control by setting the driver in the high impedance state during the transition period of the switching of the switching element.

### CROSS-REFERENCE TO RELATED APPLICATION

This application claims priority to Japanese Patent Application No. 2024-110342 filed on Jul. 9, 2024, the entire disclosure of which is incorporated herein by reference.

### BACKGROUND ART

The present disclosure relates to a driving device for a switching element.

A driving device described in PCT International Publication No. 2011/052398 drives a switching element. The switching element includes a control terminal, a first terminal, and a second terminal. When a voltage is applied to the control terminal, a current flows between the first terminal and second terminal.

The driving device includes a driver and a resistor. The driver includes two switches connected in series to each other. A node between the two switches is connected to the control terminal of the switching element through the resistor. The driver outputs a driving signal that switches between a low level and a high level to the control terminal.

When the driving signal at the high level is output, the voltage is applied to the control terminal, which turns on the switching element. When the driving signal at the low level is output, electric charges accumulated in the control terminal flows through the resistor and its electric energy is consumed at the resistor, which turns off the switching element.

The driving device may perform active gate control (hereinafter, called active control). The active control is control in which the voltage applied to the control terminal is changed during switching transition of the switching element to suppress voltage surge. For example, there is known active control in which the driving signal at the opposite level of its previous state is temporarily output to the control terminal to suppress a ratio of voltage change at the control terminal near an end of a transition period of the switching. In this active control, at turn-on of the switching element, the driving signal at a high level is output to the control signal to transition the switching element from an off-state to an on-state, and the driving signal at a low level is temporarily output to the control terminal during this transition period. At turn-off of the switching element, the driving signal at the low level is output to the control signal to transition the switching element from the on-state to the off-state, and the driving signal at the high level is temporarily output to the control terminal during this transition period. Here, a speed of change of the voltage applied to the control terminal varies also depending on a resistance value of the resistor connected in series to the control terminal.

As the resistance value of the resistor connected in series to the control terminal is decreased, a switching speed of the switching element is increased. A switching speed of switching elements such as a silicon carbide (SIC) semiconductor and a gallium nitride (GaN) semiconductor, which have recently been put into practical use in recent years, is fast, and in order to utilize this characteristic, the resistance value of the resistor connected to the control terminal tends to be set low. On the other hand, when the resistance value of the resistor connected to the control terminal is set low, the voltage applied to the control terminal in the active control is changed during a short period, so that in the above-described active control, an impact of the voltage change at the control terminal due to the driving signal at the opposite level of its previous state, which is temporarily output, becomes significant. When the change of the voltage applied to the control terminal is attempted to be kept within a proper range, control of an output time of the driving signal temporarily output to the control terminal becomes complicated. That is, precise time control is required. It is considered that the resistance value of the resistor connected in series to the control terminal is set high in order to suppress complexity of controllability in consideration of the active control; however, this may decrease the switching speed of the switching element. In other words, it is difficult to set the resistance value of the resistor connected to the control terminal. The present disclosure has been made in order to solve the above-described problem and is directed to providing active control in which a resistance value of a resistor connected in series to a control terminal is easily set.

### SUMMARY

In accordance with an aspect of the present disclosure, there is provided a driving device for a switching element including a first terminal, a second terminal, and a control terminal. The driving device includes a driver configured to switch the switching element on and off by generating a driving signal based on a control signal that switches between a low level and a high level and by inputting the driving signal from an output terminal of the driver to the control terminal, a first resistor through which the output terminal is connected to the control terminal, and a second resistor through which the control terminal is connected to the second terminal. The driving device performs active control in which a voltage applied to the control terminal is adjusted during a transition period of switching of the switching element. A state of the driver includes a high output state in which the driving signal at a high level is input from the output terminal to the control terminal, a low output state in which the driving signal at a low level is input from the output terminal to the control terminal, and a high impedance state in which the driving signal is not input to the control terminal. The driving device performs the active control by setting the driver in the high impedance state during the transition period of the switching of the switching element.

Other aspects and advantages of the disclosure will become apparent from the following description, taken in conjunction with the accompanying drawings, illustrating by way of example the principles of the disclosure.

### BRIEF DESCRIPTION OF THE DRAWINGS

The disclosure, together with objects and advantages thereof, may best be understood by reference to the following description of the embodiments together with the accompanying drawings in which:

FIG. 1 is a configuration diagram of a driving device for a switching element;

FIG. 2 is a diagram illustrating a high output state of a driver;

FIG. 3 is a diagram illustrating a low output state of the driver;

FIG. 4 is a diagram illustrating a high impedance state of the driver;

FIG. 5 is a timing diagram illustrating a relationship between time and voltage; and

FIG. 6 is a diagram illustrating a high impedance state of a driver according to a modification.

### DETAILED DESCRIPTION OF THE EMBODIMENTS

The following will describe an embodiment of a driving device for a switching element according to the present disclosure.

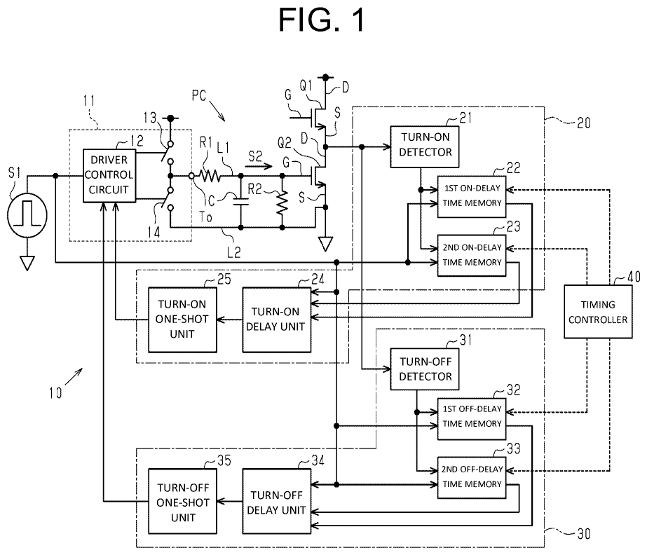

As illustrated in FIG. 1, a power converter PC includes a switching element Q1 as a high-side switch and a switching element Q2 as a low-side switch. A load, which is not illustrated, is connected to a node between the switching element Q1 and the switching element Q2. The power converter PC performs power conversion of an input power and outputs the converted power to the load. The switching elements Q1, Q2 are, for example, metal oxide semiconductor field effect transistors (MOSFETs). The switching elements Q1, Q2 may be made of a semiconductor material such as silicon carbide (SiC) and gallium nitride (GaN). The switching element Q2 includes a gate G, a drain D, and a source S. The gate G is an example of the control terminal in the present disclosure. The drain D is an example of the first terminal in the present disclosure. The source S is an example of the second terminal in the present disclosure. The switching elements Q1, Q2 may be switching elements such as insulated gate bipolar transistors, other than MOSFETs. When each of the switching elements Q1, Q2 is an insulated gate bipolar transistor, the base is an example of the control terminal, the collector is an example of the first terminal, and the emitter is an example of the second terminal, in the present disclosure.

The power converter PC includes a driving device 10 for a switching element. The driving device 10 for the switching element switches the switching elements Q1, Q2 on and off. As an example, the following will describe the driving device 10 for the switching element, which is provided for the switching element Q2; however, the same driving device 10 for the switching element is provided also for the switching element Q1.

The driving device 10 for the switching element includes a driver 11. The driver 11 has, for example, a driver control circuit 12, a first switch 13, a second switch 14 connected in series to the first switch 13, and an output terminal To, for example. The first switch 13 and the second switch 14 are, for example, transistors. A terminal of the first switch 13, which is different from a terminal connected to the second switch 14, is connected to a control power supply. A node between the first switch 13 and the second switch 14 is connected to the output terminal To.

The driving device 10 for the switching element includes a first connection line L1 through which the output terminal To is connected to the gate G and a second connection line L2 through which the second switch 14 is connected to the source S. A terminal of the second switch 14, which is different from a terminal connected to the first switch 13, is connected to the source S through the second connection line L2.

The driving device 10 for the switching element includes a gate resistor R1 as the first resistor, a resistor R2 as the second resistor, and a capacitor C. The gate resistor R1 is provided on the first connection line L1. The output terminal To is connected to the gate G through the gate resistor R1. The resistor R2 and the capacitor C are provided between the gate resistor R1 and the gate G and one terminal of each of the resistor R2 and the capacitor C is connected to the first 30 connection line L1 and the other terminal is connected to the second connection line L2. The gate G is connected to the source S through the resistor R2. A resistance value of the gate resistor R1 is smaller than that of the resistor R2. The gate resistor R1 is a gate resistor that is connected to the gate G. The resistor R2 is a gate-to-source resistor through which the gate G is connected to the source S.

A control signal S1 is input to the driver control circuit 12. The control signal S1 is, for example, a signal that is determined by comparing a voltage command and a carrier signal. The control signal S1 is output from an IC, for example. The control signal S1 is a pulse signal that switches between a low level and a high level. At a rising edge of the control signal S1, the control signal S1 is transitioned from the low level to the high level. At a falling edge of the control signal S1, the 10) control signal S1 is transitioned from the high level to the low level.

The driver 11 generates a driving signal S2 based on the control signal S1 and outputs the driving signal S2 from the output terminal To. The driving signal S2 output from the output terminal To is input to the gate G of the switching element Q2 through the first connection line L1. The driving signal S2 is a signal for switching the switching element Q2 on and off. The driving signal S2 is a pulse signal that switches between a low level and a high level. At a rising edge of the driving signal S2, the driving signal S2 is transitioned from the low level to the high level. At a falling edge of the driving signal S2, the driving signal S2 is transitioned form the high level to the low level.

The driver control circuit 12 controls the first switch 13 and the second switch 14 according to the control signal S1 and an output from a turn-on one-shot unit 25 or a turn-off one-shot unit 35, which will be described later. A state of the driver 11 changes depending on the control of the first switch 13 and the second switch 14 of the driver control circuit 12. The state of the driver 11 includes a high output state, a low output state, and a high impedance state.

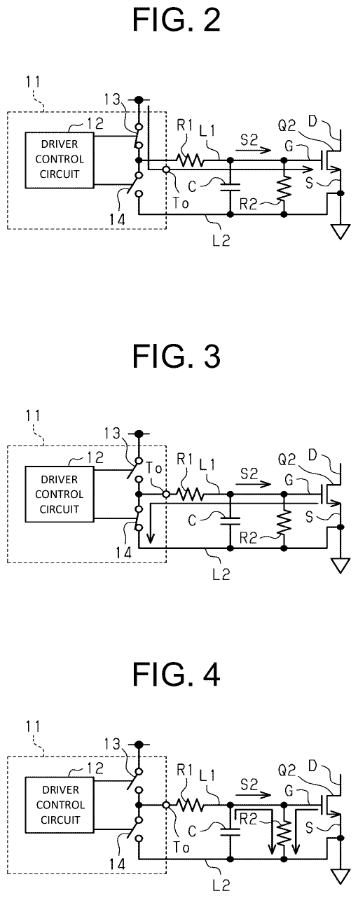

As illustrated in FIG. 2, the high output state is a state in which the driving signal S2 at the high level is input from the output terminal To to the gate G. In the high output state, the first switch 13 is turned on and the second switch 14 is turned off. When the first switch 13 is turned on and the second switch 14 is turned off, the driving signal S2 at the high level is output from the driver 11. Thus, the switching element Q2 is turned on by a voltage from the control power supply.

As illustrated in FIG. 3, the low output state is a state in which the driving signal S2 at the low level is input from the output terminal To to the gate G. In the low output state, the first switch 13 is turned off and the second switch 14 is turned on. When the first switch 13 is turned off and the second switch 14 is turned on, the driving signal S2 at the low level is output from the driver 11. As a result, the voltage applied to the gate G is decreased by a current flowing to the source S through the gate resistor R1.

As illustrated in FIG. 4, the high impedance state is a state in which the driving signal S2 is not input to the gate G. In the high impedance state, the first switch 13 and the second switch 14 are turned off. As a result, since the output terminal To is not connected to the control power supply and a ground, the output terminal To has a high impedance. In the high impedance state, the output terminal To is electrically isolated from the gate G, so that the voltage applied to the gate G is decreased by a current flowing to the source S through the resistor R2. In addition, a current flows from the capacitor C to the source S through the resistor R2.

### <Turn-on Processing Circuit>

As illustrated in FIG. 1, the driving device 10 for the switching element includes a turn-on processing circuit 20. The turn-on processing circuit 20 performs a turn-on processing. In the turn-on processing, active control is performed at turn-on of the switching element Q2.

The active control is control in which the voltage applied to the gate G is adjusted during a transition period of the switching of the switching element Q2 to suppress voltage surge. The transition period of the switching of the switching element Q2 includes at least one of a transition period from an on-state to an off-state in the switching element Q2 and a transition period from the off-state to the on-state in the switching element Q2. Here, the voltage surge includes ringing and overshoot of a drain-to-source voltage Vds.

The active control performed at turn-on is control in which a period of time when the driver 11 is in the high impedance state is set during the transition period from the off-state to the on-state in the switching element Q2.

The turn-on processing circuit 20 includes a turn-on detector 21 that detects that the switching element Q2 is turned on. The turn-on detector 21 detects that the switching element Q2 is turned on by comparing the drain-to-source voltage Vds with an on-threshold value. When the driving signal S2 goes to the high level, a gate-to-source voltage Vgs increases. When the gate-to-source voltage Vgs reaches a predetermined value or more, the switching element Q2 is turned on. When the switching element Q2 is turned on, the drain-to-source voltage Vds decreases. Thus, the turn-on detector 21 may detect that the switching element Q2 is turned on by determining whether the drain-to-source voltage Vds is less than the on-threshold value or not.

The on-threshold value is the predetermined value. The on-threshold value is determined so that a start of a drop of the drain-to-source voltage Vds is detectable. The start of the drop of the drain-to-source voltage Vds refers to a specific point in a period of time from when the drain-to-source voltage Vds starts to drop actually to before the drain-to-source voltage Vds drops completely. When the on-threshold value is set in this way, the turn-on detector 21 detects the start of the drop of the drain-to-source voltage Vds. The drain-to-source voltage Vds is an example of the voltage between the first terminal and the second terminal in the present disclosure.

The turn-on detector 21 has, for example, a comparator. The drain-to-source voltage Vds and the on-threshold value are input to the comparator. The comparator outputs a signal at a low level when the drain-to-source voltage Vds is equal to or more than the on-threshold value. The comparator outputs a signal at a high level when the drain-to-source voltage Vds is less than the on-threshold value. At a rising edge of an output of the turn-on detector 21, the output of the turn-on detector 21 is transitioned from the low level to the high level.

The turn-on processing circuit 20 includes a first on-delay time memory 22 and a second on-delay time memory 23 as the on-delay time memory. The control signal S1 and the output of the turn-on detector 21 are input to the first on-delay time memory 22 and the second on-delay time memory 23. The first on-delay time memory 22 and the second on-delay time memory 23 store a period of time from 10) the rising edge of the control signal S1 to the rising edge of the output of the turn-on detector 21 as the on-delay time of the switching element Q2. The switching element Q2 has a transition period from the rising edge of the driving signal S2 following the rising edge of the control signal S1 to the rising edge of the output of the turn-on detector 21 following the point of time when the drain-to-source voltage Vds reaches less than the on-threshold value. This transition period is the on-delay time.

The first on-delay time memory 22 and the second on-delay time memory 23 are, for example, each formed of an integrating circuit using a capacitor. While a constant current flows into the capacitor for the period of time from the rising edge of the control signal S1 to the rising edge of the output of the turn-on detector 21, the capacitor stores electric charges corresponding to the on-delay time. As a result, the first on-delay time memory 22 and the second on-delay time memory 23 store the on-delay time as a voltage across the capacitor.

The turn-on processing circuit 20 includes a turn-on delay unit 24. The turn-on delay unit 24 receives the control signal S1 and reads the on-delay time from one of the first on-delay time memory 22 and the second on-delay time memory 23. For example, the turn-on delay unit 24 reads the on-delay time by generating a current corresponding to the voltage of each capacitor of the first on-delay time memory 22 and the second on-delay time memory 23. The turn-on delay unit 24 may correct the on-delay time read from the first on-delay time memory 22 or the second on-delay time memory 23 according to a propagation delay time from the start of the drop of the drain-to-source voltage Vds to the rising edge of the output of the turn-on detector 21. For example, the turn-on delay unit 24 may subtract the propagation delay time from the on-delay time read from the first on-delay time memory 22 or the second on-delay time memory 23 to correct the on-delay time. The propagation delay time only needs to be obtained in advance by an experiment or a simulation. The turn-on delay unit 24 outputs a point of time when the on-delay time has elapsed after the rising edge of the control signal S1.

The turn-on processing circuit 20 includes a turn-on one-shot unit 25. The turn-on one-shot unit 25 outputs a negative pulse to the driver control circuit 12 at the point of time output from the turn-on delay unit 24. The negative pulse intervenes with the control signal S1 to set the driver 11 in the high impedance state.

While the negative pulse is input to the driver control circuit 12 from the turn-on one-shot unit 25, even when the control signal S1 is at the high level, the driver control circuit 12 controls the first switch 13 and the second switch 14 so that the driver 11 is set in the high impedance state. Even when the control signal S1 is at the high level, in a case where the negative pulse is not input to the driver 20 control circuit 12 from the turn-on one-shot unit 25, the driver control circuit 12 controls the first switch 13 and the second switch 14 so that the driver 11 is set in the high output state.

Thus, the turn-on one-shot unit 25 sets the period of time when the driver 11 is in the high impedance state within a period of time when the control signal S1 is at the high level. A width of the negative pulse may be constant or variable. In a case where the width of the negative pulse is set variable, for example, the width only needs to be changed according to a load condition.

The driving device 10 for the switching element includes a timing controller 40. The timing controller 40 controls the driving device 10 for the switching element. The timing controller 40, at the turn-on, stores the on-delay time in one of the first on-delay time memory 22 and the second on-delay time memory 23 and causes the turn-on delay unit 24 to read the on-delay time from the other of the first on-delay time memory 22 and the second on-delay time memory 23.

One control cycle is defined as a period of time while the control signal S1 goes to the high level, is transitioned to the low level, and goes to the high level again. The timing controller 40 alternately switches between the first on-delay time memory 22 and the second on-delay time memory 23 so that one of the first on-delay time memory 22 and the second on-delay time memory 23 stores the on-delay time while the on-delay time is read into the turn-on delay unit 24 from the other thereof. That is, at each turn-on, the timing controller 40 switches between the first on-delay time memory 22 and the second on-delay time memory 23 to store the on-delay time therein. As a result, at each turn-on, the timing controller 40 switches between the first on-delay time memory 22 and the second on-delay time memory 23 from which the on-delay time is read into the turn-on delay unit 24.

During a control cycle in which the timing controller 40 stores the on-delay time in the first on-delay time memory 22, the on-delay time is read into the turn-on delay unit 24 from the second on-delay time memory 23. During a control cycle in which the timing controller 40 stores the on-delay time in the second on-delay time memory 23, the on-delay time is read into the turn-on delay unit 24 from the first on-delay time memory 22. Thus, at the turn-on, the on-delay time stored in the first on-delay time memory 22 or the second on-delay time memory 23 at previous turn-on is read into the turn-on delay unit 24. Accordingly, the point of time when the turn-on one-shot unit 25 outputs the negative pulse is set based on the on-delay time at the previous turn-on of the switching element Q2. Note that the turn-on detector 21, the first on-delay time memory 22, and the second on-delay time memory 23 may be reset, for example, after a predetermined time has elapsed or by a predetermined signal such as the control signal S1 and the driving signal S2.

As described above, the turn-on processing is the processing in which at the turn-on of the switching element Q2, the on-delay time is stored and the period of time when the driver 11 is in the high impedance state is set within the period of time when the control signal S1 is at the high level based on the on-delay time at the previous turn-on of the switching element Q2.

### <Turn-Off Processing Circuit>

The driving device 10 for the switching element includes a turn-off processing circuit 30. The turn-off processing circuit 30 performs a turn-off processing. In the turn-off processing, the active control is performed at turn-off of the switching element Q2. The active control performed at the turn-off is control in which the voltage applied to the gate G is adjusted during the transition period from the on-state to the off-state in the switching element Q2 to suppress the voltage surge.

The turn-off processing circuit 30 includes a turn-off detector 31 that detects that the switching element Q2 is turned off. The turn-off detector 31 detects that the switching element Q2 is turned off by comparing the drain-to-source voltage Vds with an off-threshold value. When the driving signal S2 goes to the low level, the gate-to-source voltage Vgs decreases. When the gate-to-source voltage Vgs reaches less than a predetermined value, the switching element Q2 is turned off. 20 When the switching element Q2 is turned off, the drain-to-source voltage Vds increases. Thus, the turn-off detector 31 may detect that the switching element Q2 is turned off by determining whether the drain-to-source voltage Vds is equal to or more than the off-threshold value or not.

The off-threshold value is the predetermined value. The off-threshold value is determined so that a start of a rise of the drain-to-source voltage Vds is detectable. The start of the rise of the drain-to-source voltage Vds refers to a specific point in a period of time from when the drain-to-source voltage Vds starts to rise actually to before the drain-to-source voltage Vds rises completely. When the off-threshold value is set in this way, the turn-off detector 31 detects the start of the rise of the drain-to-source voltage Vds.

The turn-off detector 31 has, for example, a comparator. The drain-to-source voltage Vds and the off-threshold value are input to the comparator. The comparator outputs a signal at a high level when the drain-to-source voltage Vds is equal to or more than the off-threshold value. The comparator outputs a signal at a low level when the drain-to-source voltage Vds is less than the off-threshold value. At a rising edge of an output of the turn-off detector 31, the output of the turn-off detector 31 is transitioned from the low level to the high level.

The turn-off processing circuit 30 includes a first off-delay time memory 32 and a second off-delay time memory 33 as the off-delay time memory. The control signal S1 and the output of the turn-off detector 31 are input to the first off-delay time memory 32 and the second off-delay time memory 33. The first off-delay time memory 32 and the second off-delay time memory 33 store a period of time from the falling edge of the control signal S1 to the rising edge of the output of the turn-off detector 31 as the off-delay time of the switching element Q2. The switching element Q2 has a transition period from the falling edge of the driving signal S2 following the falling edge of the control signal S1 to the rising edge of the output of the turn-off detector 31 following the point of time when the drain-to-source voltage Vds reaches the off-threshold value or more. This transition period is the off-delay time.

The first off-delay time memory 32 and the second off-delay time memory 33 are, for example, each formed of an integrating circuit using a capacitor. While a constant current flows into the capacitor for the period of time from the falling edge of the control signal S1 to the rising edge of the output of the turn-off detector 31, the capacitor stores electric charges corresponding to the off-delay time. As a result, the first off-delay time memory 32 and the second off-delay time memory 33 store the off-delay time as a voltage across the capacitor.

The turn-off processing circuit 30 includes a turn-off delay unit 34. The turn-off delay unit 34 receives the control signal S1 and reads the off-delay time from one of the first off-delay time memory 32 and the second off-delay time memory 33. For example, the turn-off delay unit 34 reads the off-delay time by generating a current corresponding to the voltage of each capacitor of the first off-delay time memory 32 and the second off-delay time memory 33. The turn-off delay unit 34 may correct the off-delay time read from the first off-delay time memory 32 or the second off-delay time memory 33 according to a propagation delay time from the start of the rise of the drain-to-source voltage Vds to the rising edge of the output of the turn-off detector 31. For example, the turn-off delay unit 34 may subtract the propagation delay time from the off-delay time read from the first off-delay time memory 32 or the second off-delay time memory 33 to correct the off-delay time. The propagation delay time only needs to be obtained in advance by an experiment or a simulation. The turn-off delay unit 34 outputs a point of time when the off-delay time has elapsed after the falling edge of the control signal S1.

The turn-off processing circuit 30 includes a turn-off one-shot unit 35. The turn-off one-shot unit 35 outputs a positive pulse to the driver control circuit 12 at the point of time output from the turn-off delay unit 34. The positive pulse intervenes with the control signal S1 to set the driver 11 in the high impedance state.

While the positive pulse is input to the driver control circuit 12 from the turn-off one-shot unit 35, even when the control signal S1 is at the low level, the driver control circuit 12 controls the first switch 13 and the second switch 14 so that the driver 11 is set in the high impedance state. When the control signal S1 is at the low level and no positive pulse is input to the driver control circuit 12 from the turn-off one-shot unit 35, the driver control circuit 12 controls the first switch 13 and the second switch 14 so that the driver 11 is set in the low output state.

Thus, the turn-off one-shot unit 35 sets the period of time when the driver 11 is in the high impedance state within a period of time when the control signal S1 is at the low level. A width of the positive pulse may be constant or variable. In a case where the width of the positive pulse is set variable, for example, the width only needs to be changed according to the load condition.

The timing controller 40, at the turn-off, stores the off-delay time in one of the first off-delay time memory 32 and the second off-delay time memory 33 and causes the turn-off delay unit 34 to read the off-delay time from the other of the first off-delay time memory 32 and the second off-delay time memory 33.

The timing controller 40 alternately switches between the first off-delay time memory 32 and the second off-delay time memory 33 so that one of the first off-delay time memory 32 and the second off-delay time memory 33 stores the off-delay time while the off-delay time is read into the turn-off delay unit 34 from the other thereof. That is, at each turn-off, the timing controller 40 switches between the first off-delay time memory 32 and the second off-delay time memory 33 to store the off-delay time therein. As a result, at each turn-off, the timing controller 40 switches between the first off-delay time memory 32 and the second off-delay time memory 33 from which the off-delay time is read into the turn-off delay unit 34.

During a control cycle in which the timing controller 40 stores the off-delay time in the first off-delay time memory 32, the off-delay time is read into the turn-off delay unit 34 from the second off-delay time memory 33. During a control cycle in which the timing controller 40 stores the off-delay time in the second off-delay time memory 33, the off-delay time is read into the turn-off delay unit 34 from the first off-delay time memory 32. Thus, at the turn-off, the off-delay time stored in the first off-delay time memory 32 or the second off-delay time memory 33 at previous turn-off is read into the turn-off delay unit 34. Accordingly, the point of time when the turn-off one-shot unit 35 outputs the positive pulse is set based on the off-delay time at the previous turn-off of the switching element Q2. Note that the turn-off detector 31, the first off-delay time memory 32, and the second off-delay time memory 33 may be reset, for example, after a predetermined time has elapsed or by a predetermined signal such as the control signal S1 and the driving signal S2.

As described above, the turn-off processing is the processing in which at the turn-off of the switching element Q2, the off-delay time is stored and the period of time when the driver 11 is in the high impedance state is set within the period of time when the control signal S1 is at the low level based on the off-delay time at the previous turn-off of the switching element Q2.

### Operation of Present Embodiment

The following will describe operation of the present embodiment. As an example, the following will describe a case where the active control is not performed in the first control cycle, active control of a comparative example is performed in the second control cycle, and the active control of the present embodiment is performed of the third control cycle.

The active control of the comparative example is control in which the driving signal S2 is switched between the high level and the low level to suppress voltage surge. In the active control of the comparative example, the driver 11 is set in the low output state when the turn-on one-shot unit 25 outputs a negative pulse, and the driver 11 is set in the high output state when the turn-off one-shot unit 35 outputs a positive pulse. Accordingly, in the active control of the comparative example, at the turn-on of the switching element Q2, a period of time when the driving signal S2 is at the low level is set within a period of time when the control signal S1 is at the high level. In addition, at the turn-off of the switching element Q2, a period of time when the driving signal S2 is at the high level is set within a period of time when the control signal S1 is at the low level.

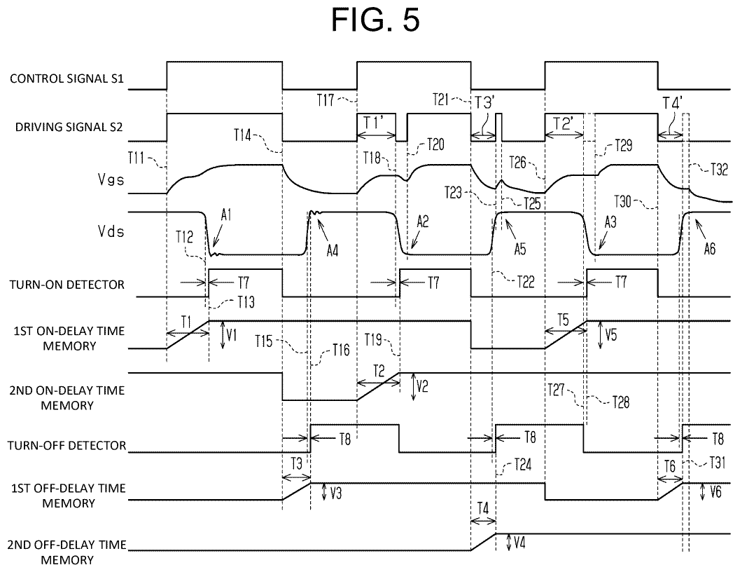

As illustrated in FIG. 5, when the first control cycle starts at a time T11, the control signal S1 goes to the high level. Then, when the driving signal S2 goes to the high level following the control signal S1, the gate-to-source voltage Vgs increases. When the drain-to-source voltage Vds reaches the on-threshold value at a time T12, the output of the turn-on detector 21 goes to the high level at a time T13. The first on-delay time memory 22 stores an on-delay time T1 from the time T11 to the time T13 as a capacitor voltage V1 in its integrating circuit. A period of time from the time T12 to the time T13 corresponds to a propagation delay time T7 of the turn-on detector 21. The propagation delay time T7 is a time from the start of the drop of the drain-to-source voltage Vds to the rising edge of the output of the turn-on detector 21.

When the control signal S1 goes to the low level at a time T14, the driving signal S2 goes to the low level. As a result, the gate-to-source voltage Vgs decreases. When the drain-to-source voltage Vds reaches the off-threshold value at a time T15, the output of the turn-off detector 31 goes to the high level at a time T16. The first off-delay time memory 32 stores an off-delay time T3 from the time T14 to the time T16 as a capacitor voltage V3 in its integrating circuit. A period of time from the time T15 to the time T16 corresponds to a propagation delay time T8 of the turn-off detector 31. The propagation delay time T8 is a time from the start of the rise of the drain-to-source voltage Vds to the rising edge of the output of the turn-off detector 31.

When the second control cycle (in which the active control of the comparative example is performed) starts at a time T17, the control signal S1 goes to the high level. Then, when the driving signal S2 goes to the high level following the control signal S1, the gate-to-source voltage Vgs increases. The turn-on delay unit 24 reads the on-delay time T1 stored in the first on-delay time memory 22 in the first control cycle. The on-delay time T1 is the on-delay time at the previous 20 turn-on. The turn-on one-shot unit 25 outputs the negative pulse to the driver 11 at a time T18 after an on-delay time T1′ has elapsed since the time T17. This allows the period of time when the driving signal S2 is at the low level, which is the opposite level of its previous state, to be set within the period of time when the control signal S1 is at the high level. The driving signal S2 is kept at the low level from the time T18 to a time T20. The on-delay time T1′ may be equal to the on-delay time T1, or may be a time obtained by subtracting the propagation delay time T7 from the on-delay time T1.

The time T18 coincides with a point of time when the drain-to-source voltage Vds reaches the on-threshold value. This is because the load condition fluctuates little in two successive control cycles, so that a period of time when the control signal S1 is kept at the high level is the same or substantially the same. Accordingly, a point of time when the drain-to-source voltage Vds reaches the on-threshold value at the current turn-on is estimated based on the on-delay time T1 at the previous turn-on. Then, at this point of time, the driving signal S2 is set to the low level.

The output of the turn-on detector 21 goes to the high level at a time T19. The second on-delay time memory 23 stores an on-delay time T2 from the time T17 to the time T19 as a capacitor voltage V2 in its integrating circuit.

When the control signal S1 goes to the low level at a time T21, the driving signal S2 goes to the low level. As a result, the gate-to-source voltage Vgs decreases. The turn-off delay unit 34 reads the off-delay time T3 stored in the first off-delay time memory 32 in the first control cycle. The off-delay time T3 is the off-delay time at the previous turn-off. The turn-off one-shot unit 35 outputs the positive pulse to the driver 11 at a time T23 after an off-delay time T3′ has elapsed since the time T21. This allows the period of time when the driving signal S2 is at the high level, which is the opposite level of its previous state, to be set within the period of time when the control signal S1 is at the low level. The driving signal S2 is kept at the high level from the time T23 to a time T25. The off-delay time T3′ may be equal to the off-delay time T3, or may be a time obtained by subtracting the propagation delay time T8 from the off-delay time T3.

The time T23 is little different from a time T22 when the drain-to-source voltage Vds reaches the off-threshold value. Thus, although there is a case where the time T23 when the driving signal S2 goes to the high level does not coincide with the time T22, as compared with a case where the driving signal S2 is set to the high level after the turn-off detector 31 detects that the switching element Q2 is turned off, a period of time from when the drain-to-source voltage Vds reaches the off-threshold value until the driving signal S2 goes to the high level is shortened.

The output of the turn-off detector 31 goes to the high level at a time T24. The second off-delay time memory 33 stores an off-delay time T4 from the time T21 to the time T24 as a capacitor voltage V4 in its integrating circuit.

When the third control cycle (in which the active control of the present embodiment is performed) starts at a time T26, the control signal S1 goes to the high level. Then, when the driving signal S2 goes to the high level following the control signal S1, the gate-to-source voltage Vgs increases. The turn-on delay unit 24 reads the on-delay time T2 stored in the second on-delay time memory 23 in the second control cycle. The on-delay time T2 is the on-delay time at the previous turn-on. The turn-on one-shot unit 25 outputs the negative pulse to the driver 11 at a time T27 after an on-delay time T2′ has elapsed since the time T26. The on-delay time T2′ may be equal to the on-delay time T2, or may be a time obtained by subtracting the propagation delay time T7 from the on-delay time T2. As a result, the driver 11 is set in the high impedance state. The driver 11 is kept in the high impedance state from the time T27 to a time T29.

When the driver 11 is set in the high impedance state, the gate-to-source voltage Vgs is kept at a value just before the driver 11 is set in the high impedance state due to a gate capacitance and the capacitor C. In addition, a speed of change of the gate-to-source voltage Vgs is determined by the resistance value of the resistor R2. As the resistance value of the resistor R2 is decreased, the speed of the change of the gate-to-source voltage Vgs is increased. Accordingly, the speed of the change of the gate-to-source voltage Vgs when the driver 11 is in the high impedance state is adjusted by the resistance value of the resistor R2. It is suppressed that the gate-to-source voltage Vgs fluctuates when the driver 11 is in the high impedance state by setting the resistance value of the resistor R2 larger than the that of the gate resistor R1.

The output of the turn-on detector 21 goes to the high level at a time T28. The first on-delay time memory 22 stores an on-delay time T5 from the time T26 to the time T28 as a capacitor voltage V5 in its integrating circuit. This on-delay time T5 is used at the next turn-on.

When the control signal S1 goes to the low level at a time T30, the driving signal S2 goes to the low level. As a result, the gate-to-source voltage Vgs decreases. The turn-off delay unit 34 reads the off-delay time T4 stored in the second off-delay time memory 33 in the second control cycle. The off-delay time T4 is the off-delay time at the previous turn-off. The turn-off one-shot unit 35 outputs the positive pulse to the driver 11 at a time T31 after an off-delay time T4′ has elapsed since the time T30. The off-delay time T4′ may be equal to the off-delay time T4, or may be a time obtained by subtracting the propagation delay time T8 from the off-delay time T4. As a result, the driver 11 is set in the high impedance state. The driver 11 is kept in the high impedance state from the time T31 to a time T32. It is suppressed that the gate-to-source voltage Vgs fluctuates by setting the driver 11 in the high impedance state.

The output of the turn-off detector 31 goes to the high level at the time T31. The first off-delay time memory 32 stores an off-delay time T6 from the time T30 to the time T31 as a capacitor voltage V6 in its integrating circuit. This off-delay time T6 is used at the next turn-off.

As illustrated by a reference sign A1 in FIG. 5, the active control is not performed in the first control cycle, so that voltage surge occurs in the drain-to-source voltage Vds at the turn-on. In contrast, the increase in the gate-to-source voltage Vgs is temporarily suppressed in the second control cycle in which the active control of the comparative example is performed, so that as illustrated by a reference sign A2, the occurrence of voltage surge in the drain-to-source voltage Vds is suppressed. Also when the active control of the present embodiment is performed, the increase in the gate-to-source voltage Vgs is temporarily suppressed, so that as illustrated by a reference sign A3, the occurrence of voltage surge in the drain-to-source voltage Vds is suppressed. When the active control of the comparative example and the active control of the present embodiment are compared with each other, the driving signal at the opposite level of its previous state is output in the active control of the comparative example and an impact due to such a driving signal is significant, so that the gate-to-source voltage Vgs is decreased while the active control is performed. On the other hand, in the active control of the present embodiment, the gate-to-source voltage Vgs fluctuates little while the active control is performed.

As illustrated by a reference sign A4 in FIG. 5, the active control is not performed in the first control cycle, so that voltage surge occurs in the drain-to-source voltage Vds at the turn-off. In contrast, the decrease in the gate-to-source voltage Vgs is temporarily suppressed in the second control cycle in which the active control of the comparative example is performed, so that as illustrated by a 10) reference sign A5, the occurrence of voltage surge in the drain-to-source voltage Vds is suppressed. Also when the active control of the present embodiment is performed, the decrease in the gate-to-source voltage Vgs is temporarily suppressed, so that as illustrated by a reference sign A6 in FIG. 2, the occurrence of voltage surge in the drain-to-source voltage Vds is suppressed. When the active control of the comparative example and the active control of the present embodiment are compared with each other, the driving signal at the opposite level of its previous state is output in the active control of the comparative example and an impact due to such a driving signal is significant, so that the gate-to-source voltage Vgs is increased while the active control is performed. On the other hand, in the active control of the present embodiment, the gate-to-source voltage Vgs fluctuates little while the active control is performed.

### Advantageous Effect of Present Embodiment

(1) When the active control of the present embodiment is performed, the driver 11 is set in the high impedance state during the transition period of the switching of the switching element Q2. In the high impedance state, the voltage applied to the gate G is changed according to the resistance value of the resistor R2. The resistance value of the gate resistor R1 does not contribute to the change of the voltage applied to the gate G while the active control is performed. Thus, the present embodiment provides the active control in which the gate resistor R1 is easily set.

The resistance value of the resistor R2 may be set to a value suitable for the active control. The gate-to-source voltage Vgs is hardly changed by setting the resistance value of the resistor R2 larger than that of the gate resistor R1, as compared with the case where the active control of the comparative example is performed. The change of the gate-to-source voltage Vgs is easily kept within a proper range, so that complexity of controllability is suppressed.

(2) The driving device 10 for the switching element performs the turn-on 10) processing. In the turn-on processing, the period of time when the driver 11 is in the high impedance state is set within the period of time when the control signal S1 is at the high level based on the on-delay time. The period of time when the driver 11 is in the high impedance state is set using the on-delay time at the previous turn-on, so that the driver 11 does not need to be set in the high impedance state just after the switching element Q2 is detected to be turned on. Since the load condition fluctuates little in the successive control cycles, the period of time when the control signal S1 is kept at the high level is the same or substantially the same in the successive control cycles. Thus, the on-delay time at the previous turn-on and the on-delay time at the current turn-on are regarded as the same. The period of time when the driver 11 is in the high impedance state may be set using the on-delay time at the previous turn-on.

In a case where a feedback control in which the driver 11 is set in the high impedance state after the switching element Q2 is detected to be turned on is performed, when the switching speed of the switching element Q2 is fast, the feedback may not be provided until the switching transition, so that the voltage surge may not be suppressed. On the contrary, the voltage surge is suppressed using the on-delay time at the previous turn-on, regardless of the switching speed of the switching element Q2.

In addition, the on-delay time is the period of time from the rising edge of the control signal S1 to the start of the drop of the drain-to-source voltage Vds. After the drain-to-source voltage Vds drops, the voltage surge may occur. Thus, in a case where the on-delay time is defined as a period of time from the rising edge of the control signal S1 until when the drain-to-source voltage Vds completely drops, the voltage surge may not be suppressed. On the contrary, the voltage surge is suppressed by defining the on-delay time as the period of time from the rising edge of the control signal S1 to the start of the drop of the drain-to-source voltage Vds.

(3) The driving device 10 for the switching element performs the turn-off processing. In the turn-off processing, the period of time when the driver 11 is in the high impedance state is set within the period of time when the control signal S1 is at the low level based on the off-delay time. The period of time when the driver 11 is in the high impedance state is set using the off-delay time at the previous turn-off, so that the driver 11 does not need to be set in the high impedance state just after the switching element Q2 is detected to be turned off. Since the load condition fluctuates little in the successive control cycles, the period of time when the control signal S1 is kept at the high level is the same or substantially the same in the successive control cycles. Thus, the off-delay time at the previous turn-off and the off-delay time at the current turn-off are regarded as the same. The period of time when the driver 11 is in the high impedance state may be set using the off-delay time at the previous turn-off.

In a case where a feedback control in which the driver 11 is set in the high impedance state after the switching element Q2 is detected to be turned off is performed, when the switching speed of the switching element Q2 is fast, the feedback may not be provided until the switching transition, so that the voltage surge may not be suppressed. On the contrary, the voltage surge is suppressed using the off-delay time at the previous turn-off, regardless of the switching speed of the switching element Q2.

In addition, the off-delay time is the period of time from the falling edge of the control signal S1 to the start of the rise of the drain-to-source voltage Vds. After the drain-to-source voltage Vds rises, the voltage surge may occur. Thus, in a case where the off-delay time is defined as a period of time from the falling edge of the control signal S1 until when the drain-to-source voltage Vds completely rises, the voltage surge may not be suppressed. On the contrary, the voltage surge is suppressed by defining the off-delay time as the period of time from the falling edge of the control signal S1 to the start of the rise of the drain-to-source voltage Vds.

(4) The first switch 13 and the second switch 14 are turned off in the high impedance state. The driver 11 is set in the high impedance state by turning off the first switch 13 and the second switch 14 in the driver 11. Since the driver 11 is set in the high impedance state using the existing components, there is no need to add any components for setting the driver 11 in the high impedance state.

(5) The timing controller 40 stores the on-delay time in one of the first on-delay time memory 22 and the second on-delay time memory 23 and causes the turn-on delay unit 24 to read the on-delay time from the other of the first on-delay time memory 22 and the second on-delay time memory 23. In addition, at each turn-on, the timing controller 40 alternately switches between the first on-delay time memory 22 and the second on-delay time memory 23 to store the on-delay time therein. This allows, at the turn-on, the on-delay time at the current turn-on to be stored in one of the first on-delay time memory 22 and the second on-delay time memory 23 and allows the period of time when the driver 11 is in the high impedance state to be set based on the on-delay time at the previous turn-on.

(6) The turn-on delay unit 24 corrects the on-delay time read from the first on-delay time memory 22 or the second on-delay time memory 23 according to the propagation delay time of the turn-on detector 21. There is a delay from the start of the drop of the drain-to-source voltage Vds until the turn-on detector 21 detects the start of the drop of the drain-to-source voltage Vds. The driver 11 may be set in the high impedance state at an appropriate time by correcting the on-delay time according to the propagation delay time due to this delay.

(7) The timing controller 40, at the turn-off, stores the off-delay time in one of the first off-delay time memory 32 and the second off-delay time memory 33 and causes the turn-off delay unit 34 to read the off-delay time from the other of the first off-delay time memory 32 and the second off-delay time memory 33. In addition, at each turn-off, the timing controller 40 alternately switches between the first off-delay time memory 32 and the second off-delay time memory 33 to store the off-delay time therein. This allows, at the turn-off, the off-delay time at the current turn-off to be stored in one of the first off-delay time memory 32 and the second off-delay time memory 33 and allows the period of time when the driver 11 is in the high impedance state to be set based on the off-delay time at the previous turn-off.

(8) The turn-off delay unit 34 corrects the off-delay time read from the first off-delay time memory 32 or the second off-delay time memory 33 according to the propagation delay time of the turn-off detector 31. There is a delay from the start of the rise of the drain-to-source voltage Vds until the turn-off detector 31 detects the start of the rise of the drain-to-source voltage Vds. The driver 11 may be set in the high impedance state at an appropriate time by correcting the off-delay time according to the propagation delay time due to this delay.

(9) At the turn-on of the switching element Q2, the period of time when the driver 11 is in the high impedance state is set within the period of time when the control signal S1 is at the high level. Furthermore, at the turn-off of the switching element Q2, the period of time when the driver 11 is in the high impedance state is set within the period of time when the control signal S1 is at the low level. Accordingly, as compared with a configuration in which resistors that are connected to the gate G are switched, it is not necessary to provide a plurality of the resistors nor a switch for switching between the resistors.

(10) The driving device 10 for the switching element includes the capacitor C. When SiC semiconductors are used as the switching elements Q1, Q2, as the drain-to-source voltage Vds of one of the two switching elements Q1, Q2 rises, the drain-to-source voltage Vds of the other of the two switching elements Q1, Q2 may be changed. As a result, an unintentional change in the voltage at the gate G may lead malfunctions of the switching elements Q1, Q2. The voltage at the gate G is stabilized by providing the capacitor C in the driving device 10 for the switching element, which prevents the malfunctions of the switching elements Q1, Q2.

### Modification

The embodiment may be modified as follows. The embodiment and the following modifications may be combined with each other as long as they do not technically contradict each other.

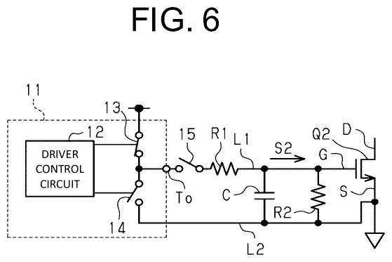

As illustrated in FIG. 6, the driving device 10 for the switching element may include a switch 15 that is provided between the output terminal To and the gate G. In this case, the switch 15 is turned off in the high impedance state. When the switch 15 is turned off, the output terminal To is electrically isolated from the gate G. In this case, the driving device 10 for the switching element includes a switch controller that switches the switch 15 on and off. The switch controller turns off the switch 15 when the negative pulse is input from the turn-on one-shot unit 25 to the switch controller. The switch controller turns off the switch 15 when the positive pulse is input from the turn-off one-shot unit 35 to the switch controller. The switch controller turns on the switch 15 when neither the negative pulse from the turn-on one-shot unit 25 nor the positive pulse from the turn-off one-shot unit 35 is input to the switch controller.

The driver 11 is set in the high impedance state by turning off the switch 15. Thus, even when the driver 11 itself do not have a function to be set in the high impedance state by turning off both the first switch 13 and the second switch 14, this configuration sets the driver 11 in the high impedance state.

The driving device 10 for the switching element only needs to perform at least one of the turn-on processing and the turn-off processing. When the driving device 10 for the switching element performs only the turn-on processing, the driving device 10 for the switching element need not include the turn-off processing circuit 30. When the driving device 10 for the switching element performs only the turn-off processing, the driving device 10 for the switching element need not include the turn-on processing circuit 20.

When the driving device 10 for the switching element does not perform the turn-on processing, the active control of the comparative example may be performed at the turn-on of the switching element Q2. That is, the driving device for the switching element may perform control so that the driver 11 is set in the low output state when the turn-on one-shot unit 25 outputs the negative pulse, at the turn-on of the switching element Q2.

When the driving device 10 for the switching element does not perform the turn-off processing, the active control of the comparative example may be performed at the turn-off of the switching element Q2. That is, the driving device for the switching element may perform control so that the driver 11 is set in the high output state when the turn-off one-shot unit 35 outputs the positive pulse, at the turn-off of the switching element Q2.

When the driving device 10 for the switching element performs the turn-on processing, the driving device 10 for the switching element may set the driver 11 in the high impedance state after the turn-on detector 21 detects that the switching element Q2 is turned on. That is, the on-delay time at the previous turn-on need not be used as the on-delay time.

When the driving device 10 for the switching element performs the turn-off processing, the driving device 10 for the switching element may set the driver 11 in the high impedance state after the turn-off detector 31 detects that the switching element Q2 is turned off. That is, the off-delay time at the previous turn-off need not be used as the off-delay time.

As long as the first on-delay time memory 22 and the second on-delay time memory 23 store the on-delay time, the first on-delay time memory 22 and the second on-delay time memory 23 may have any configuration. For example, the first on-delay time memory 22 and the second on-delay time memory 23 may be formed of a digital circuit using a counter. Similarly, as long as the first off-delay time memory 32 and the second off-delay time memory 33 store the off-delay time, the first off-delay time memory 32 and the second off-delay time memory 33 may have any configuration.

The driving device 10 for the switching element need not include the capacitor C. In this case, the switching elements Q1, Q2 may be made of a semiconductor material different from the SiC.

### Definition

The wording “at least one” used in the present specification means “one or more” of desired options. As an example, the wording “at least one” used in the present specification means “only one option” or “both two options” when the number of options is two. As another example, the wording “at least one” used in the present specification means “only one option” or “any combination of two or more options” when the number of options is three or more.

What is claimed is:

1. A driving device for a switching element including a first terminal, a second terminal, and a control terminal, the driving device comprising:
a driver configured to switch the switching element on and off by generating a driving signal based on a control signal that switches between a low level and a high level and by inputting the driving signal from an output terminal of the driver to the control terminal;
a first resistor through which the output terminal is connected to the control terminal; and
a second resistor through which the control terminal is connected to the second terminal,
the driving device performing active control in which a voltage applied to the control terminal is adjusted during a transition period of switching of the switching element, wherein
a state of the driver includes:
a high output state in which the driving signal at a high level is input from the output terminal to the control terminal;
a low output state in which the driving signal at a low level is input from the output terminal to the control terminal; and
a high impedance state in which the driving signal is not input to the control terminal, and
the driving device performs the active control by setting the driver in the high impedance state during the transition period of the switching of the switching element.

2. The driving device for the switching element according to claim 1, wherein
the driving device for the switching element performs at least one of a turn-on processing at turn-on of the switching element or a turn-off processing at turn-off of the switching element,
in the turn-on processing, the active control is performed by storing an on-delay time from a rising edge of the control signal to a start of a drop of a voltage between the first terminal and the second terminal and setting a period of time when the driver is in the high impedance state within a period of time when the control signal is at the high level based on the on-delay time at previous turn-on, and
in the turn-off processing, the active control is performed by storing an off-delay time from a falling edge of the control signal to a start of a rise of the voltage between the first terminal and the second terminal and setting a period of time when the driver is in the high impedance state within a period of time when the control signal is at the low level based on the off-delay time at previous turn-off.

3. The driving device for the switching element according to claim 1, wherein
the driver includes:
a first switch connected to a control power supply; and
a second switch connected in series to the first switch,
a node between the first switch and the second switch is connected to the output terminal, and
the first switch and the second switch are turned off in the high impedance state.

4. The driving device for the switching element according to claim 1, the driving device further comprising
a switch provided between the output terminal and the control terminal, wherein
the switch is turned off in the high impedance state.
